(19) United States
(12) Patent Application Publication
(10) Pub. No.: US 2025/0116713 A1
(43) Pub. Date: Apr. 10, 2025

(54) METHOD OF ESTIMATING STATE OF CHARGE OF BATTERY AND SYSTEM THEREOF

(71) Applicant: Richtek Technology Corporation, Hsinchu (TW)

(72) Inventors: Chieh-En CHEN, Hsinchu (TW); Chang-Yu HO, Hsinchu (TW)

(21) Appl. No.: 18/909,907

(22) Filed: Oct. 8, 2024

Related U.S. Application Data
(60) Provisional application No. 63/589,308, filed on Oct. 10, 2023.

(30) Foreign Application Priority Data
Sep. 25, 2024 (TW) 113136362

(51) Int. Cl. G01R 31/3835; G01R 31/367

(52) U.S. Cl. CPC G01R 31/3835; G01R 31/367

(57) ABSTRACT

The present invention discloses a method of estimating a state of charge (SOC) of a battery and a system thereof. The method of estimating the SOC of the battery includes following steps: calculating a voltage difference (ΔV) using a voltaic gauge based on a battery voltage (VBAT) and an open-circuit voltage (OCV); adaptively adjusting a gain (K) using a gain control engine based on a battery current (IBAT) and a full charged capacity (FCC), wherein the gain (K) is adjusted to generate an adjusted gain (K′); generating a present SOC change (ΔSOC_T) using the voltaic gauge based on the voltage difference (ΔV) and the adjusted gain (K′); and generating a next SOC (SOC_T+1) using an accumulator based on a present SOC (SOC_T) and the present SOC change (ΔSOC_T).

### CROSS REFERENCE

The present invention claims priority to U.S. 63/589,308 filed on Oct. 10, 2023 and claims priority to TW 113136362 filed on Sep. 25, 2024.

### BACKGROUND OF THE INVENTION

### Field of Invention

The present invention relates to a method of estimating a state of charge (SOC) of a battery; particularly, it relates to such method and system capable of adaptively adjusting the gain for estimating the SOC of a battery.

### Description of Related Art

For users of portable electronic devices, the state of charge (SOC) is essential information. A fully charged battery displays an SOC of 100%, while a fully discharged battery shows an SOC of 0%. There is an urgent need to estimate SOC using algorithms embedded within portable electronic devices. Prior art often employs current coulomb integrators to progressively calculate the charge or discharge capacity of a battery. Combined with the total battery capacity, the SOC can be determined. However, current coulomb integrators may accumulate errors due to design inaccuracies or external noise, leading to inaccurate SOC estimations.

Currently, in battery management systems available on the market, pure voltage-type voltaic gauges (voltaic gauges) estimate the battery's SOC by measuring the battery voltage and relying on the correlation between a battery voltage and SOC. The advantage of this method lies in its simplicity and the ability to achieve stable SOC convergence by referencing the open-circuit voltage (OCV) curve, thereby avoiding divergence.

However, pure voltage-type voltaic gauges also have some obvious disadvantages listed below:

First, incorrect SOC trends during drastic current changes: When the charging and discharging directions remain the same but the current changes drastically, pure voltage-type voltaic gauges may provide incorrect SOC trends, failing to accurately reflect the actual SOC of the battery.

Second, inaccurate SOC rate of change under different environmental conditions: Under varying loads, temperatures, battery capacities, or aging conditions, pure voltage-type voltaic gauges may lead to inaccurate SOC rate changes, making it unreliable to estimate the actual state of the battery.

Third, inability to effectively cope with variable operating environments: Although pure voltage-type voltaic gauges have the advantage of stable convergence by relying on the OCV curve, they cannot adequately respond to changes in load, temperature, battery capacity, and aging degree. They lack sufficient compensation to ensure SOC accuracy.

Therefore, existing pure voltage-type voltaic gauges may produce inaccurate SOC estimations under certain extreme conditions, necessitating improvements in such technologies to address the above issues.

In view of the above, to overcome the drawbacks in the prior art, the present invention proposes a method and system for estimating the SOC of a battery with adaptively adjusted gain.

### SUMMARY OF THE INVENTION

From one perspective, the present invention provides a method of estimating a state of charge (SOC) of a battery, comprising: (a) calculating a voltage difference (ΔV) using a voltaic gauge based on a battery voltage (VBAT) and an open-circuit voltage (OCV); (b) adaptively adjusting a gain (K) using a gain control engine based on a battery current (IBAT) and a full charged capacity (FCC), wherein the gain (K) is adjusted to generate an adjusted gain (K′); (c) generating a present SOC change (ΔSOC_T) using the voltaic gauge based on the voltage difference (ΔV) and the adjusted gain (K′); and (d) generating a next SOC (SOC_T+1) using an accumulator based on a present SOC (SOC_T) and the present SOC change (ΔSOC_T).

In one embodiment, the step (b) further includes: the gain control engine further adaptively adjusts the gain (K) based on the gain (K) before adjustment and the voltage difference (ΔV) to generate the adjusted gain (K′).

In one embodiment, the steps (a), (b), (c), and (d) are executed sequentially, and after the step (d), the method repeats by using the next SOC (SOC_T+1) as the present SOC (SOC_T) in step (a).

In one embodiment, in the step (b), the gain control engine adjusts the gain by increasing or decreasing a fixed gain difference.

In one embodiment, in the step (b), the gain control engine further adjusts the gain based on a current difference between a previous battery current (IBAT_T−1) and the battery current (IBAT).

In one embodiment, in the step (b), when the voltage difference does not exceed a predetermined voltage difference or the battery current does not exceed a predetermined current, it is defined as a light-load condition, wherein the gain control engine adjusts and maintains the gain at a fixed light-load gain.

In one embodiment, the step (b) includes: the gain control engine compares a previous SOC change (ΔSOC_T−1) with a target change value (ΔSOCI) and adaptively adjusts the gain thereby, wherein the target change value (ΔSOCI) is related to the battery current and the full charged capacity (FCC).

In one embodiment, the full charged capacity (FCC) is related to a load condition, a battery temperature (TBAT), and/or a battery aging degree (AGS).

In one embodiment, the step (c) includes: estimating a weight based on the battery voltage using a voltage weighting model, wherein the voltage weighting model is a first predetermined relationship between the battery voltage and the weight in battery information collected during charging, discharging, and relaxing; estimating a fuzzy voltage difference based on the voltage difference using a voltage difference model, wherein the voltage difference model is a second predetermined relationship between the voltage difference and the fuzzy voltage difference; and generating the present SOC change (ΔSOC_T) based on the weight, the fuzzy voltage difference, and the gain.

In one embodiment, the method further includes: before generating the next SOC (SOC_T+1), collecting battery information under different charging/discharging currents.

In one embodiment, the method further includes: establishing the voltage weighting model and the voltage difference model by estimating the SOC and the battery voltage under different charging/discharging currents.

In one embodiment, the method further includes: calculating the weight by a difference between battery voltages under the charging/discharging current and under a different charging/discharging current to establish the voltage weighting model.

In one embodiment, the method further includes: calculating the fuzzy voltage difference based on the charging/discharging current to establish the voltage difference model.

In one embodiment, the method further includes: generating the open-circuit voltage by querying a predetermined SOC and OCV relationship table based on the SOC.

From another perspective, the present invention provides a system of estimating an SOC of a battery, comprising: a voltaic gauge, configured to calculate a voltage difference (ΔV) based on a battery voltage (VBAT) and an open-circuit voltage (OCV); a gain control engine, configured to adaptively adjust a gain (K) based on a battery current (IBAT) and a full charged capacity (FCC), wherein the gain (K) is adjusted to generate an adjusted gain (K′); and an accumulator, configured to generate a next SOC (SOC_T+1) based on a present SOC (SOC_T) and a present SOC change (ΔSOC_T); wherein the voltaic gauge generates the present SOC change (ΔSOC_T) based on the voltage difference (ΔV) and the adjusted gain (K′).

In one embodiment, the gain control engine further adaptively adjusts the gain (K) based on the gain before adjustment (K) and the voltage difference (ΔV) to generate the adjusted gain (K′).

In one embodiment, the gain control engine adjusts the gain by iteratively increasing or decreasing a fixed gain difference.

In one embodiment, the gain control engine further adjusts the gain based on a current difference between a previous battery current (IBAT_T−1) and the battery current (IBAT).

In one embodiment, the gain control engine defines a light-load condition when the voltage difference does not exceed a predetermined voltage difference or the battery current does not exceed a predetermined current, and adjusts and maintains the gain at a fixed light-load gain.

In one embodiment, the gain control engine compares a previous SOC change (ΔSOC_T−1) with a target change value (ΔSOCI) and adaptively adjusts the gain thereby, wherein the target change value (ΔSOCI) is related to the battery current and the full charged capacity (FCC).

In one embodiment, the voltaic gauge includes: a weighted fuzzifier, configured to estimate a weight based on the battery voltage using a voltage weighting model, wherein the voltage weighting model is a first predetermined relationship between the battery voltage and the weight in a battery information collected during charging, discharging, and relaxing; a voltage difference fuzzifier, configured to estimate a fuzzy voltage difference based on the voltage difference using a voltage difference model, wherein the voltage difference model is a second predetermined relationship between the voltage difference and the fuzzy voltage difference; a multiplier, configured to perform multiplication on the weight and the fuzzy voltage difference to obtain their product; and a compensator, configured to compensate or calibrate the product of the weight and the fuzzy voltage difference based on the adjusted gain to generate the present SOC change (ΔSOC_T).

In one embodiment, the weighted fuzzifier and the voltage difference fuzzifier establish the voltage weighting model and the voltage difference model under different charging/discharging currents based on corresponding different SOCs and different battery voltages.

In one embodiment, the weighted fuzzifier calculates the weight based on the difference between the battery voltages at different charging/discharging currents to establish the voltage weighting model.

In one embodiment, the voltage difference fuzzifier calculates the fuzzy voltage difference based on the difference between the voltage differences at different charging/discharging currents to establish the voltage difference model.

In one embodiment, the voltaic gauge further includes a lookup table, configured to generate the open-circuit voltage by querying a predetermined SOC and OCV relationship table based on the SOC.

In one embodiment, the gain control engine further compensates the gain based on the full charged capacity (FCC), a battery temperature (TBAT), and/or a battery aging degree (AGS).

In one embodiment, the accumulator accumulates at least one previous SOC change using an inverse Z-transformation method to generate the present SOC (SOC_T).

The present invention has at least the following advantages over the prior art:

First, accurate SOC under charging and discharging conditions: even when the charging/discharging current changes drastically, the present invention can provide correct SOC.
Second, improved SOC accuracy under varying conditions: compared to the prior art, the present invention provides more accurate SOC under different battery loads, temperatures, capacities, and/or aging degrees.
Third, better response under extreme current conditions: the present invention offers superior performance under extreme current conditions compared to the prior art.
Four, simplified gain adjustment: the present invention provides a simpler and more convenient method to adjust the gain based on test results, enhancing SOC accuracy compared to the prior art.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a hardware block diagram of a system for estimating the SOC of a battery according to an embodiment of the present invention.

FIG. 2A shows a schematic diagram of the relationship between battery current IBAT and time.

FIG. 2B shows a schematic diagram of the relationship between battery voltage VBAT, open-circuit voltage OCV, and time.

FIG. 3 shows a hardware system block diagram for estimating the SOC of a battery according to another embodiment of the present invention.

FIG. 4 shows a hardware block diagram of a system for estimating the SOC of a battery according to an embodiment of the present invention.

FIGS. 5A and 5B show schematic diagrams of the related results of the weighted fuzzifier 111 and the voltage difference fuzzifier 112 in the algorithm for estimating the SOC of a battery.

FIG. 6 shows an embodiment of model establishment of a part of the voltage difference fuzzifier 112.

FIG. 7 shows another embodiment of model establishment of another part of the voltage difference fuzzifier 112 as shown in FIG. 4.

FIG. 8 shows an embodiment of model establishment of the voltage difference fuzzifier 112 as shown in FIG. 4.

FIG. 9 shows an embodiment of model establishment of the weighted fuzzifier 111 as shown in FIG. 4.

FIG. 10 shows a hardware block diagram and data tables required for the system for estimating the SOC of a battery according to an embodiment of the present invention.

FIG. 11 shows experimental results obtained after applying least mean square optimization to the algorithm described in an embodiment of the present invention.

FIG. 12 shows experimental results obtained by estimating the SOC of a battery using the system 100 as shown in FIG. 4.

FIG. 13 shows a flowchart of a method for estimating the SOC of a battery according to an embodiment of the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

The present invention relates to a method and system for estimating the SOC of a battery when the battery is in at least one of the following states: charging, discharging, or relaxing. The method and system estimate the SOC of the battery using the battery voltage (VBAT) and battery current (IBAT).

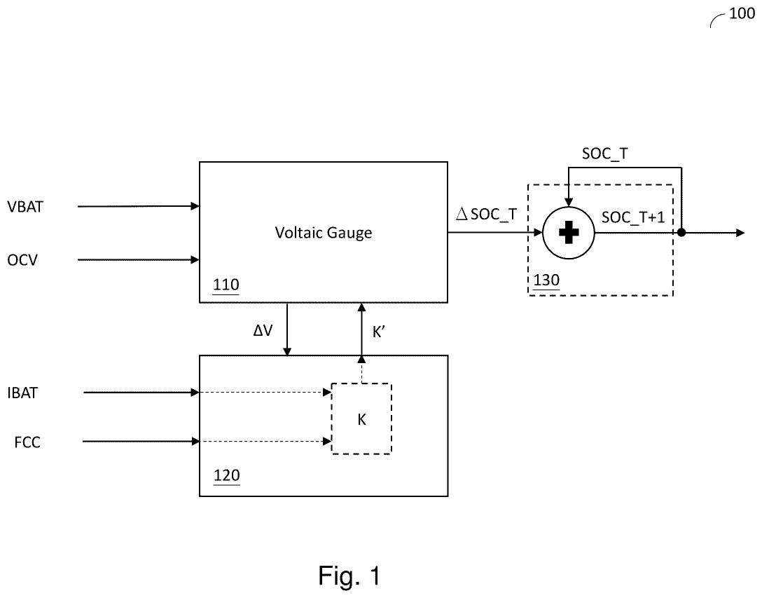

FIG. 1 shows a hardware system block diagram of a system 100 of estimating a state of charge (SOC) of a battery according to an embodiment of the present invention. As shown in FIG. 1, the system 100 includes a voltaic gauge 110, a gain control engine 120, and an accumulator 130. The voltaic gauge 110 calculates a voltage difference ΔV based on a battery voltage VBAT and an open-circuit voltage OCV. The gain control engine 120 adaptively adjusts a gain K based on a battery current IBAT and a full charged capacity FCC, wherein the gain K is adjusted to generate an adjusted gain K′. The voltaic gauge 110 generates a present SOC change ΔSOC_T based on the voltage difference ΔV and the adjusted gain K′. The accumulator 130 generates a next SOC SOC_T+1 based on a present SOC SOC_T and the present SOC change ΔSOC_T.

According to the present invention, by iteratively operating the open-circuit voltage OCV, the voltage difference ΔV, the battery voltage VBAT, and the present SOC SOC_T, and by adaptively adjusting the gain K by the gain control engine 120, the present SOC change ΔSOC_T is generated.

Unlike traditional methods purely based on voltage, which directly use the battery voltage VBAT and the open-circuit voltage OCV to generate the next SOC SOC_T+1 and can lead to sudden SOC jumps, the voltage and current compensated gain combined sensing architecture of the present invention effectively prevents such sudden jumps, maintaining SOC stability through a more stable architecture.

An advantage of the present invention is avoiding the sudden SOC changes caused by traditional pure voltage algorithms, achieving smoother and more stable SOC estimation, and providing precise compensation through the gain control engine to adapt to different operating conditions.

In one embodiment, the gain control engine 120, besides using the battery current IBAT and a full charged capacity FCC, further adaptively adjusts the gain K based on the gain K before adjustment and the voltage difference ΔV, for example, through comparing a target change value ΔSOCI with a multiplication of the gain K before adjustment and the voltage difference ΔV, wherein the target change value ΔSOCI is generated based on a quotient of the full charged capacity FCC divided by the battery current IBAT.

In one embodiment, the gain control engine 120 adjusts the gain K by iteratively increasing or decreasing a fixed gain difference. For instance, in a procedure where the SOC estimation is executed once per cycle, meaning that the time interval between a previous cycle and a present cycle, and between the present cycle and a next cycle, is one cycle, the gain control engine 120, in each cycle, adjusts the gain K before adjustment (defined as the gain K at the previous cycle) by increasing or decreasing it with a fixed gain difference based on the battery current IBAT and full charged capacity FCC, or further based on the gain K before adjustment and the voltage difference ΔV, to generate the adjusted gain K. This process is repeated over multiple cycles to continuously adjust the gain K, dynamically maintaining and adjusting the gain K.

It should be noted that, according to the method of estimating the state of charge of a battery according to the present invention, the process of estimating the state of charge is repeated multiple times, and each execution of the estimation process requires one cycle to complete. Each cycle immediately follows the previous one. In other words, the end of the previous cycle corresponds to the previous moment, the end of the current cycle corresponds to the current moment, and the end of the next cycle corresponds to the next moment.

In each iteration of the estimation process, the following steps are carried out: (1) the voltaic gauge 110 calculates the voltage difference (ΔV) based on the battery voltage (VBAT) and the open-circuit voltage (OCV); (2) the gain control engine 120 adaptively adjusts the gain (K) based on the battery current (IBAT) and the full charged capacity (FCC), providing the adjusted gain to the voltaic gauge 110; (3) the voltaic gauge 110, using the voltage difference (ΔV) and the adjusted gain (K), generates the present SOC change (ΔSOC_T); and (4) the accumulator 130 generates the next SOC (SOC_T+1) based on the present SOC (SOC_T) and the present SOC change (ΔSOC_T).

Therefore, the gain and the SOC generated at the end of the previous cycle are used in the present cycle as the gain before adjustment and the present SOC, and this process continues iteratively.

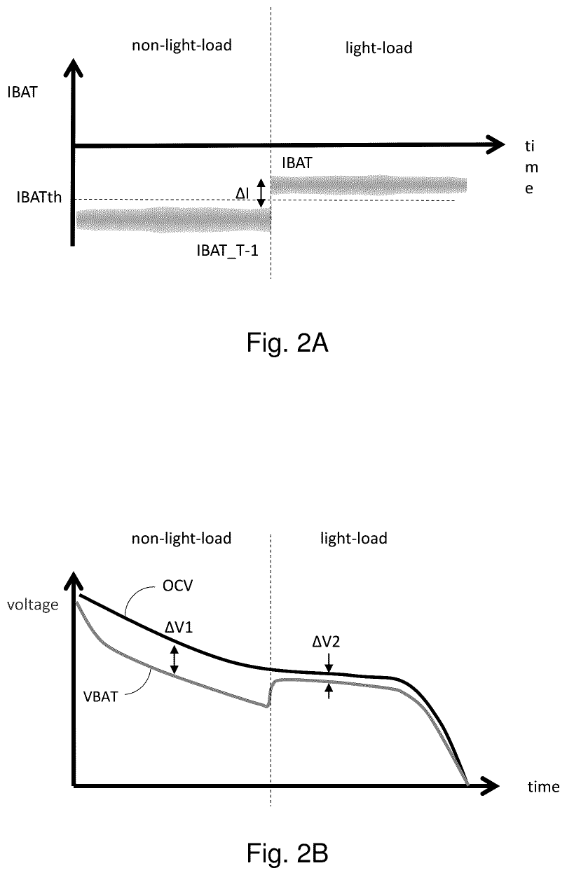

In one embodiment, the gain control engine 120 further adjusts the gain based on a current difference between a previous battery current IBAT_T−1 and the (present) battery current IBAT. For example, FIG. 2A shows a schematic diagram of a relationship between the battery current IBAT and time. As shown in FIG. 2A, when the previous battery current IBAT_T−1 is a non-light-load current and relatively high, and the present battery current IBAT is a light-load current and relatively low, causing the current difference ΔI to exceed a predetermined current difference threshold. The system 100 determines whether it operates under light-load or non-light-load conditions based on whether the current difference ΔI exceeds a predetermined current difference threshold or not, and adjusts the gain K accordingly. It should be noted that the current and current difference refer to absolute values. In another embodiment, the system 100 can directly determine whether it operates under light-load or non-light-load conditions based on the absolute value of the battery current IBAT.

In another embodiment, the gain control engine 120 defines a light-load condition when the voltage difference ΔV does not exceed a predetermined voltage difference or the battery current IBAT does not exceed a predetermined current IBATth. The gain control engine 120 adjusts and maintains the gain K at a fixed light-load gain. From another perspective, under light-load conditions, after maintaining the gain K at the fixed light-load gain, the gain control engine 120 no longer adaptively adjusts the gain K or adjusts it periodically with a relatively long cycle. FIG. 2B shows a schematic diagram of the relationship between the battery voltage VBAT, open-circuit voltage OCV, and time. As shown in FIG. 2B, in one embodiment, when the voltage difference ΔV1 exceeds a predetermined voltage difference or the battery current IBAT exceeds a predetermined current IBATth, it is defined as a non-light-load condition; when the voltage difference ΔV2 does not exceed the predetermined voltage difference, it is defined as a light-load condition. It should be noted that in the embodiment shown in FIG. 2A, the battery current IBAT is negative.

According to the present invention, under non-light-load conditions, when the voltage difference ΔV is sufficiently large, the calculation of the SOC change ΔSOC is dominated by the battery current IBAT. The combined sensing architecture of battery voltage VBAT and battery current IBAT adjusts the gain K adaptively through tracking and controlling, thereby optimizing the calculation of the SOC change ΔSOC and providing good transient response and short-term accuracy. Its performance can rival that of a Coulomb Counter but without relying on charge counting to calculate SOC, avoiding cumulative errors and saving power by eliminating the need for continuous analog-to-digital converter (CADC) conversion.

Under light-load conditions, due to the small variation in battery current IBAT measurements, the CADC error percentage increases. Therefore, the weight of the gain K is reduced, and the battery voltage dominates the calculation of the SOC change ΔSOC. The voltage difference ΔV is implemented in a self-adaptive manner, and the gain control engine 120 can periodically calibrate the SOC with a relatively long cycle to provide long-term stable SOC estimation.

It should be noted that the CADC error percentage refers to the percentage of error in the total signal caused by limitations in conversion accuracy or other influencing factors during the process of converting analog signals to digital signals. Specifically, when the CADC converts an analog signal (e.g., battery voltage or current) into a digital signal, the conversion process may be affected by resolution, noise, or quantization errors, resulting in discrepancies between the digital signal and the actual analog signal. This error is usually expressed as a percentage to quantify and analyze the accuracy of the CADC. In battery management systems, the CADC error percentage affects the measurement accuracy of voltage, current, or other parameters, thereby influencing the estimation accuracy of the battery's SOC.

In summary, according to the present invention, under non-light-load conditions, the calculation of the SOC change ΔSOC is dominated by the battery current IBAT, achieving accuracy comparable to a Coulomb Counter while avoiding cumulative errors and power consumption issues. Under light-load conditions, the calculation of the SOC change ΔSOC is dominated by the battery voltage VBAT, utilizing natural driving forces to maintain long-term stable SOC, further enhancing the system's reliability and stability.

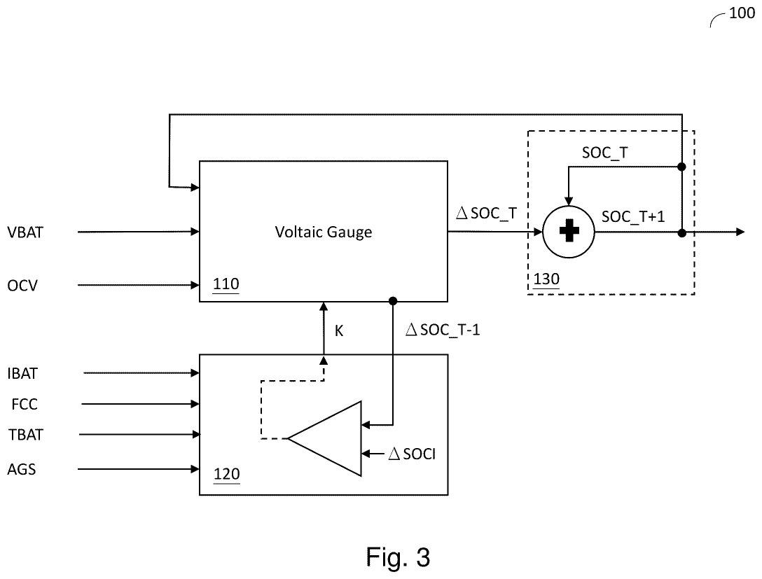

FIG. 3 shows a hardware system block diagram of estimating the SOC of a battery according to another embodiment of the present invention. As shown in FIG. 3, the system 100 includes a voltaic gauge 110, a gain control engine 120, and an accumulator 130.

In this embodiment, the gain control engine 120 compares the previous SOC change ΔSOC_T−1 with a target change value ΔSOCI and adaptively adjusts the gain K, where the target change value ΔSOCI is related to the battery current IBAT and the full charged capacity FCC. In one embodiment, the target change value ΔSOCI is positively related to the battery current IBAT. The voltage difference ΔV is positively related to the difference between the battery voltage VBAT and the open-circuit voltage OCV. In one embodiment, the target change value is also related to the full charged capacity FCC. For example, the target change value ΔSOCI is negatively related to the full charged capacity FCC and is negatively related to the quotient of the full charged capacity FCC divided by the battery current IBAT. For instance, when the previous SOC change ΔSOC_T−1 is lower than the target change value ΔSOCI, the gain K is adjusted upward; when the previous SOC change ΔSOC_T−1 is higher than the target change value ΔSOCI, the gain K is adjusted downward.

It should be noted that the full charged capacity (FCC) refers to the maximum amount of charge a battery can store when fully charged. The full charged capacity FCC is related to load conditions, battery temperature TBAT, and/or battery aging degree AGS. The FCC decreases gradually with the battery's use and aging and is an important indicator for evaluating the battery's health and performance. This is well known to those skilled in the art and will not be elaborated here.

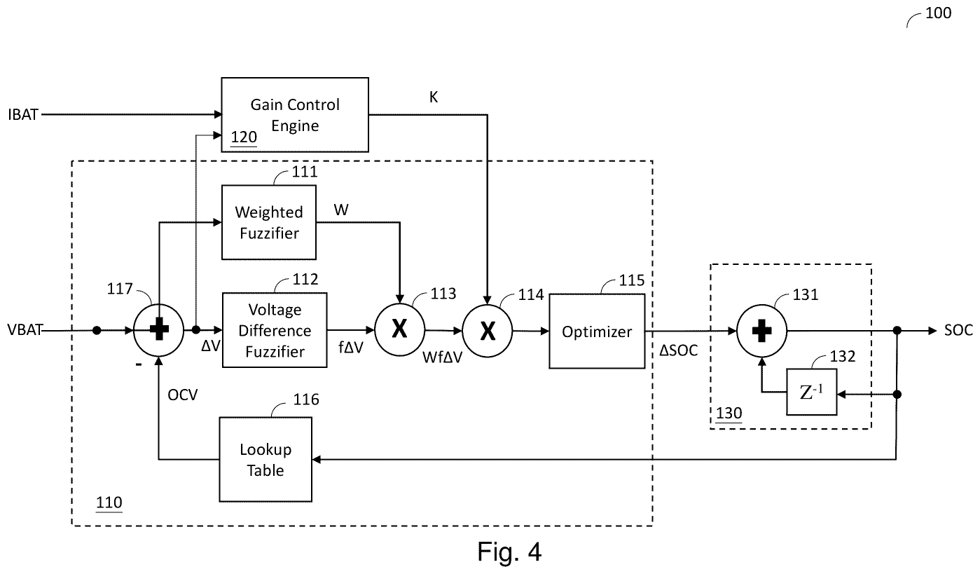

FIG. 4 shows a hardware block diagram of a system 100 of estimating the SOC of a battery according to an embodiment of the present invention. As shown in FIG. 4, this embodiment provides a more specific embodiment of the system 100. The system 100 includes a voltaic gauge 110, a gain control engine 120, and an accumulator 130. The voltaic gauge 110 includes a weighted fuzzifier 111, a voltage difference fuzzifier 112, a multiplier 113, a compensator 114, an optimizer 115, a lookup table 116, and a subtractor 117.

The weighted fuzzifier 111 estimates a weight W based on the battery voltage VBAT using a voltage weighting model, where the voltage weighting model is a first predetermined relationship between the battery voltage VBAT and the weight W in battery information collected during charging, discharging, and relaxing. The voltage difference fuzzifier 112 estimates a fuzzy voltage difference fΔV based on the voltage difference ΔV using a voltage difference model, where the voltage difference model is a second predetermined relationship between the voltage difference ΔV and the fuzzy voltage difference fΔV. The multiplier 113 performs multiplication on the weight W and the fuzzy voltage difference fΔV to obtain the product W·fΔV. The compensator 114 compensates or calibrates the product W·fΔV based on the adjusted gain K′ to generate the present SOC change ΔSOC_T. In one embodiment, the optimizer 115 can apply an additional gain to the weighted SOC change ΔSOC for optimization. The subtractor 117, for example, subtracts the open-circuit voltage OCV from the battery voltage VBAT to obtain the voltage difference ΔV.

In this embodiment, the accumulator 130 accumulates the weighted SOC change ΔSOC using, for example but not limited to, inverse Z-transformation to determine an estimated SOC. Then, the estimated SOC is fed back to the lookup table 116 to generate the estimated open-circuit voltage OCV. The system 100 repeats the above steps to estimate the SOC.

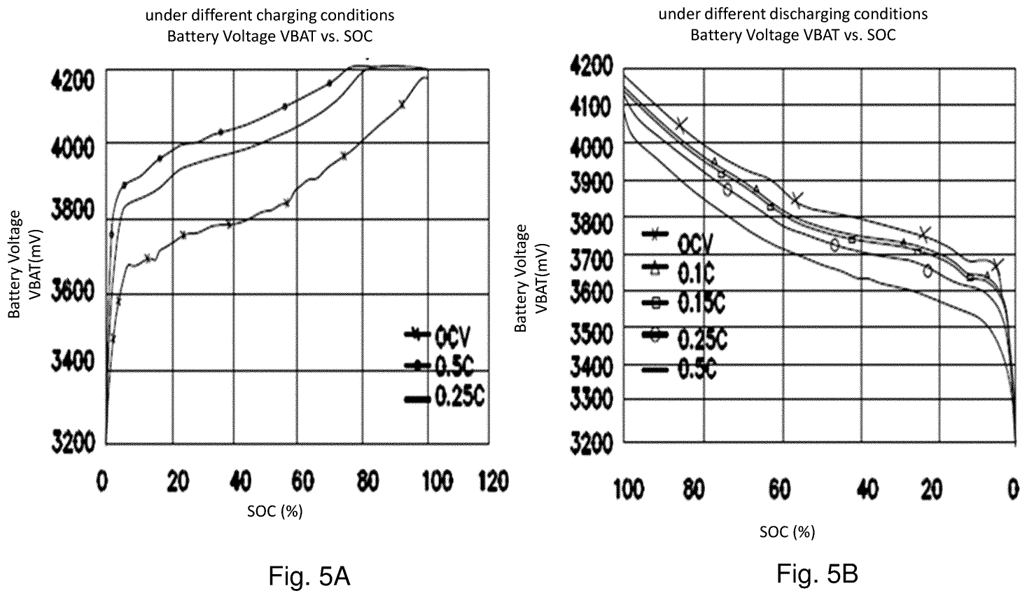

FIGS. 5A and 5B show schematic diagrams of the related results of the weighted fuzzifier 111 and the voltage difference fuzzifier 112 in the algorithm for estimating the SOC of a battery. These figures illustrate the related results before estimating the current SOC.

FIG. 5A shows the relationship between the battery voltage VBAT and the SOC under different charging conditions. The charging condition OCV represents charging the battery by 2% per hour; the charging condition 0.5C represents charging the battery by 50% per hour; the charging condition 0.25C represents charging the battery by 25% per hour. FIG. 5A shows that under the same SOC, the higher the charging rate, the higher the battery voltage VBAT.

FIG. 5B shows the relationship between the battery voltage VBAT and the SOC under different discharging conditions. The discharging condition OCV represents discharging the battery by 2% per hour; the discharging condition 0.5C represents discharging the battery by 50% per hour; the discharging condition 0.25C represents discharging the battery by 25% per hour; the discharging condition 0.15C represents discharging the battery by 15% per hour; the discharging condition 0.1C represents discharging the battery by 10% per hour. FIG. 5B shows that under the same SOC value, the higher the discharging rate, the lower the battery voltage VBAT.

The establishment of the voltage difference fuzzifier 112 as shown in FIG. 4 will be explained below.

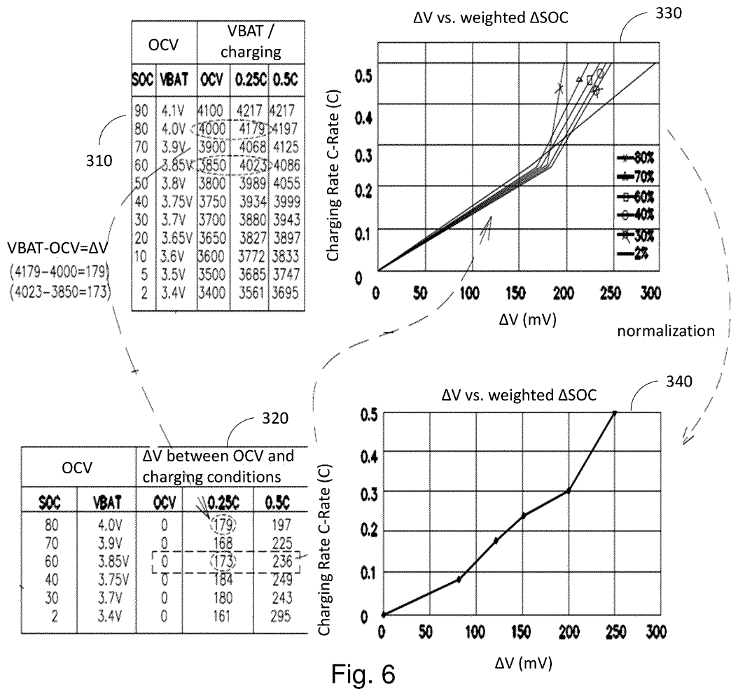

FIG. 6 shows an embodiment of model establishment of a part of the voltage difference fuzzifier 112. FIG. 6 includes Table 310, Table 320, FIG. 330, and FIG. 340. Table 310 includes data extracted from FIG. 5A. For example, under the condition where the SOC is 80%, for the charging condition representing charging the battery by 2% per hour, the battery voltage VBAT is 4000 mV. For the charging condition representing charging the battery by 25% per hour, the battery voltage VBAT is 4179 mV. Additionally, under the condition where the SOC is 60%, for the charging condition representing charging the battery by 2% per hour, the battery voltage VBAT is 3850 mV. For the charging condition representing charging the battery by 25% per hour, the battery voltage VBAT is 4023 mV.

Table 320 is generated based on the information in Table 310. For example, under the condition where the SOC is 80%, the battery's open-circuit voltage OCV (representing charging the battery by 2% per hour) is taken as a reference. The voltage difference between the battery's OCV and the battery voltage VBAT under the charging condition 0.25C (charging the battery by 25% per hour) is 179 mV (4179 mV minus 4000 mV). Similarly, under the SOC of 60%, the voltage difference is 173 mV (4023 mV minus 3850 mV). By repeating these steps, Table 320 is obtained. Based on Table 320, the relationship 330 between the voltage difference and the charging rate under different SOCs is derived. After normalization, curve 340 is obtained.

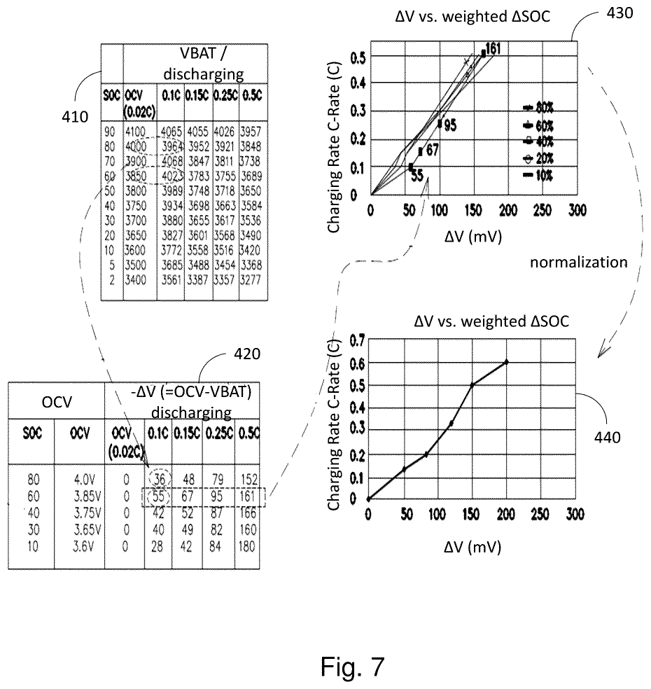

FIG. 7 shows another embodiment of model establishment of another part of the voltage difference fuzzifier 112 as shown in FIG. 4. FIG. 7 includes Table 410, Table 420, FIG. 430, and FIG. 440. Table 410 includes data extracted from FIG. 5B. For example, under the SOC of 80%, for the discharging condition of 2% per hour, the battery voltage VBAT is 4000 mV. For the discharging condition of 10% per hour, VBAT is 3964 mV. Under the SOC of 60%, for the discharging condition of 2% per hour, VBAT is 3850 mV; for 10% per hour, VBAT is 3795 mV.

Table 420 is generated based on Table 410. Under SOC of 80%, using OCV (discharging at 2% per hour) as reference, the voltage difference at 0.1C (10% per hour) is 36 mV (4000 mV minus 3964 mV). Under SOC of 60%, the voltage difference at 0.25C is 55 mV (3850 mV minus 3795 mV). Repeating these steps produces Table 420. From Table 420, the relationship 430 between voltage difference and discharging rate under different SOCs is obtained. After normalization, curve 440 is derived.

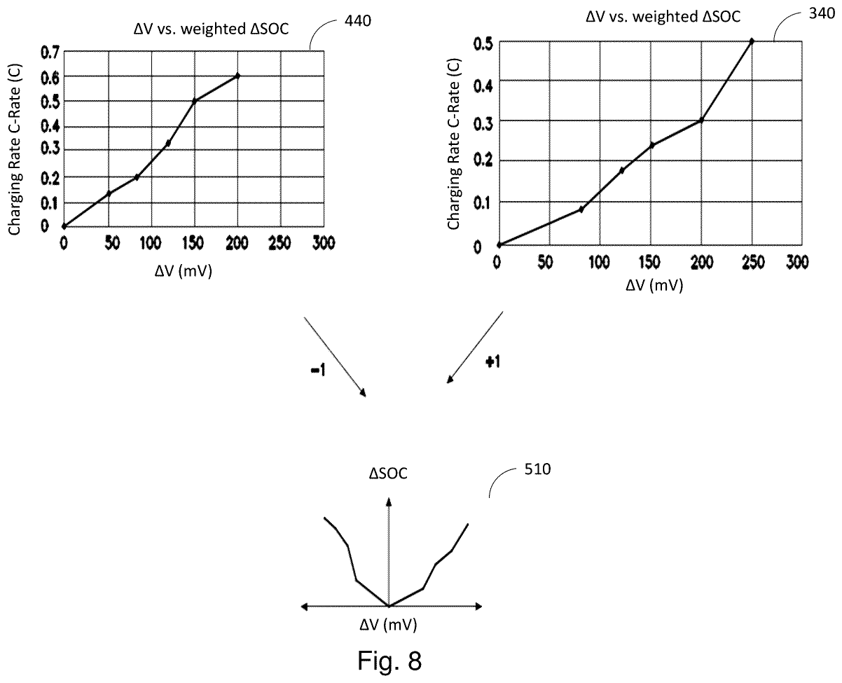

FIG. 8 shows an embodiment of model establishment of the voltage difference fuzzifier 112 as shown in FIG. 4. By combining curves 340 and 440, the voltage difference model 510 is established. The model 510 shows that the greater the absolute value of the voltage difference ΔV between the battery's OCV and VBAT under charging/discharging conditions, the higher the charging/discharging current (corresponding to ΔSOC in FIG. 4), indicating a V-shaped relationship.

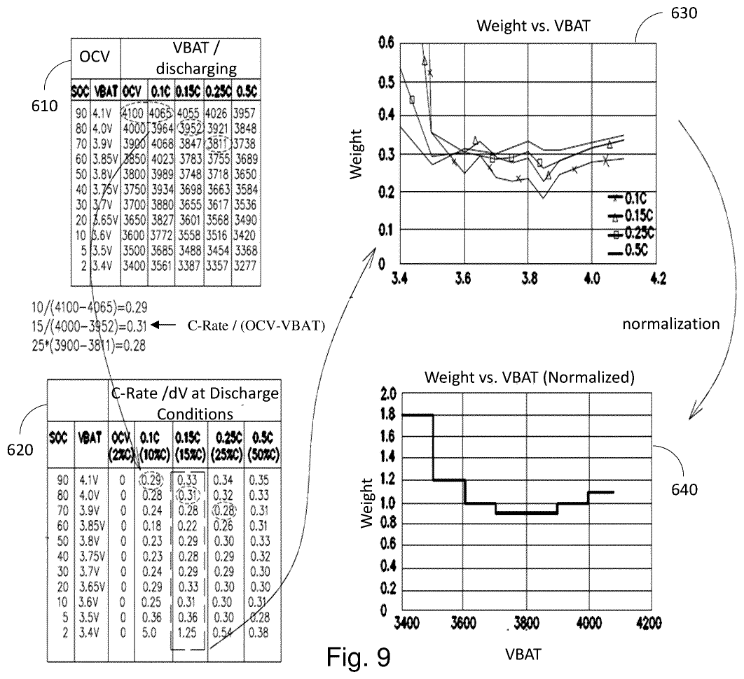

FIG. 9 shows an embodiment of model establishment of the weighted fuzzifier 111 as shown in FIG. 4. FIG. 9 includes Table 610, Table 620, FIG. 630 (relationship between VBAT and weight W), and FIG. 640 (voltage weighting model). Table 610 includes data from FIG. 5B. For SOC of 90%, VBAT is 4100 mV at 2% per hour discharging, and 4065 mV at 10% per hour. For SOC of 80%, VBAT is 4000 mV at 2% per hour, and 3952 mV at 15% per hour. For SOC of 70%, VBAT is 3900 mV at 2% per hour, and 3811 mV at 25% per hour.

Table 620 is generated from Table 610. For SOC of 90%, using OCV (2% per hour) as reference, the weight coefficient at 4.1 V and 10% per hour is 0.29 (calculated by 10/(4100−4065)). Repeating these steps gives Table 620. From Table 620, the relationship 630 between VBAT and weight W under discharging currents is derived. After normalization, the voltage weighting model 640 required by the weighted fuzzifier 111 is obtained.

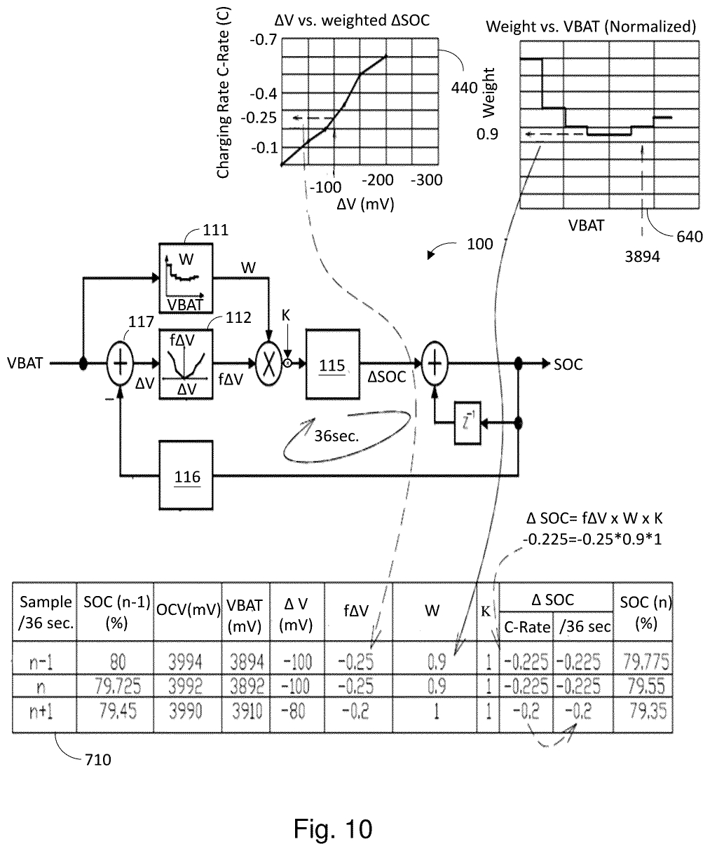

FIG. 10 shows the hardware block diagram and data tables for the system 100. The voltage difference model 510 and voltage weighting model 640 are embedded into system 100. Since the battery is discharging, part of the voltage difference model 510 (curve 440) is shown. Data table 710 corresponds to nodes in system 100.

According to the voltage weighting model 640, depending on VBAT, the weight W ranges between 0.8 and 1.8. When VBAT is 3.894 V, the weight W applied to the output of voltage difference fuzzifier 112 is 0.9.

The voltage difference ΔV is input to the voltage difference fuzzifier 112, calculated by subtracting the OCV from VBAT. The estimated SOC from system 100 is input to the OCV lookup table 116. As shown, the larger the absolute value of ΔV, the larger the absolute value of ΔSOC output by voltaic gauge 110. Curve 440 shows that when ΔV is −100 mV, ΔSOC is −0.25.

As described, ΔSOC calculated by voltage difference fuzzifier 112 is weighted by W from weighted fuzzifier 111 and optimized by optimizer 115. In one embodiment, optimizer 115 further fine-tunes ΔSOC based on least mean square optimization and the adaptive adjustment of gain K by gain control engine 120 according to IBAT.

The system 100 sums the weighted ΔSOC with accumulator 130 (e.g., using inverse Z-transformation) to determine a new SOC. This new SOC is fed back to OCV lookup table 116, and the process repeats. Data table 710 shows three battery samples, each 36 seconds apart. The operation mode of system 100 involves determining the voltage difference, applying multiple fuzzy calculations, and adaptively adjusting the gain.

Note that, the charging rate C-Rate (C)=0.2C indicates that 20% of the battery capacity is discharged in one hour, and it would take 5 hours for a full discharge. Therefore, 0.2C=20% every 3600 seconds=0.2% every 36 seconds.

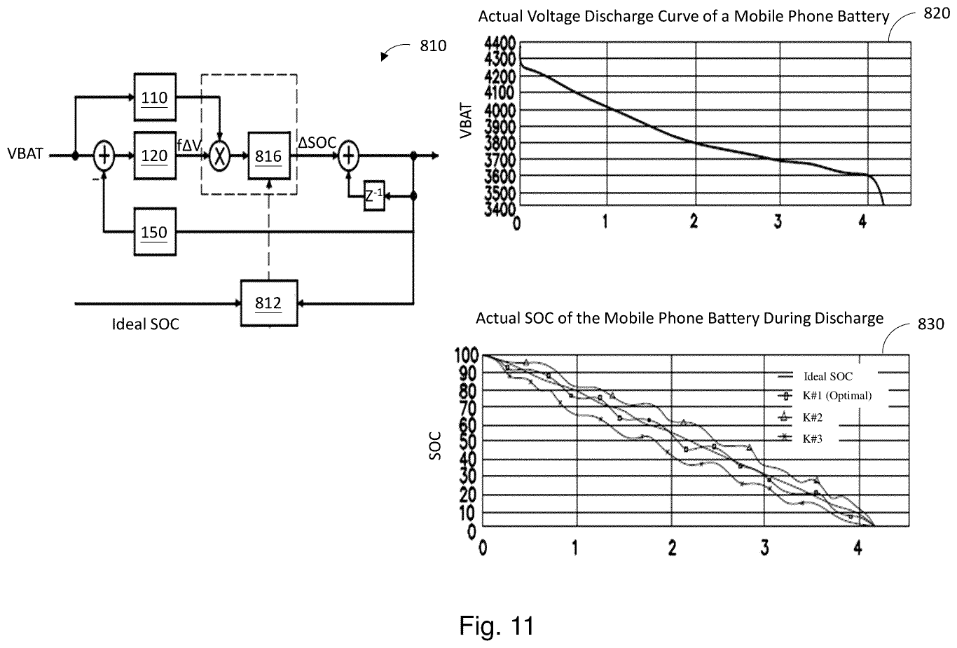

FIG. 11 shows experimental results after applying least mean square optimization to the algorithm (similar to system 100 but with an additional optimization block 812). The algorithm's voltage VBAT and SOC correspond to FIGS. 820 and 830. The least mean square optimization block 812 fine-tunes optimizer 816. Different gains (Gain #1˜Gain #3) are applied, and Gain #1 is selected as the optimal gain K.

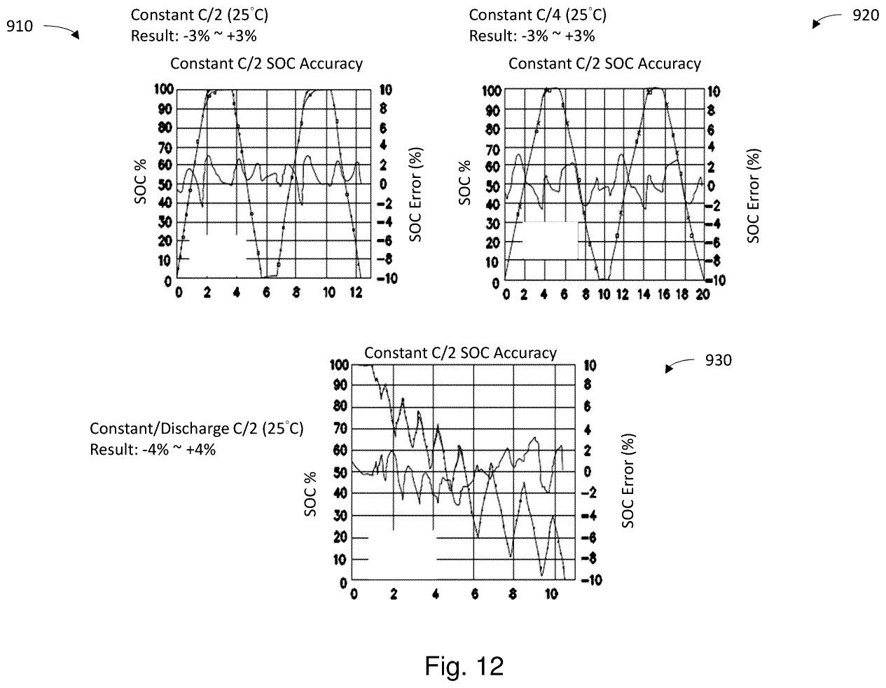

FIG. 12 shows experimental results of estimating SOC using system 100. FIGS. 910, 920, and 930 show SOC estimation errors under different charging/discharging rates. The errors range between −3% to +3% at 0.5C and 0.25C rates, and −4% to +4% at partial 0.5C rates, demonstrating the accuracy of system 100.

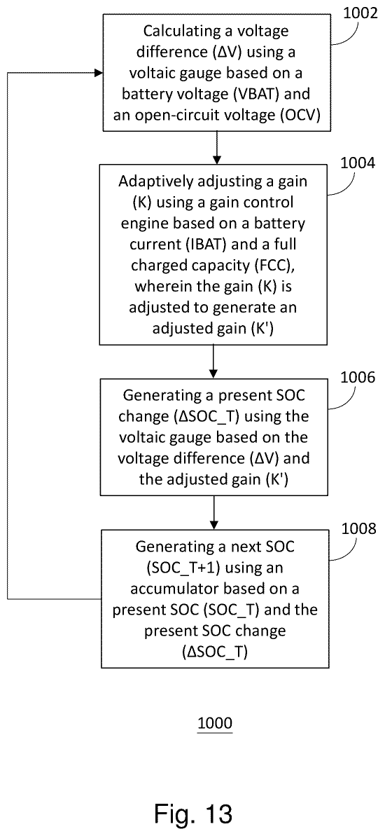

FIG. 13 shows a flowchart of a method 1000 of estimating an SOC of a battery according to an embodiment of the present invention. The method includes:
(1002) Calculating a voltage difference (ΔV) using a voltaic gauge based on a battery voltage (VBAT) and an open-circuit voltage (OCV);
(1004) Adaptively adjusting a gain (K) using a gain control engine based on a battery current (IBAT) and a full charged capacity (FCC), wherein the gain (K) is adjusted to generate an adjusted gain (K′);
(1006) Generating a present SOC change (ΔSOC_T) using the voltaic gauge based on the voltage difference (ΔV) and the adjusted gain (K′); and
(1008) Generating a next SOC (SOC_T+1) using an accumulator based on a present SOC (SOC_T) and the present SOC change (ΔSOC_T);
Returning to step (1002) with SOC_T+1 as the current SOC.

The method 1000 is iterative, dynamically adjusting and correcting the gain. If SOC estimation is no longer needed or gain adjustment is unnecessary (e.g., under light-load conditions with a fixed gain), the process stops or pauses.

In some embodiments, step (1004) further includes adjusting the gain based on the previous gain (K) and ΔV.

In some embodiments, the Gain Control Engine adjusts the gain by increasing or decreasing a fixed gain difference.

In some embodiments, the Gain Control Engine further adjusts the gain based on the current difference between IBAT_T−1 and IBAT.

In some embodiments, when ΔV does not exceed a predetermined voltage difference, it is defined as a light-load condition, and the Gain Control Engine maintains the gain at a fixed light-load gain.

In some embodiments, step (1004) includes comparing ΔSOC_T−1 with a target change value (ΔSOCI) and adjusting the gain accordingly, where ΔSOCI is related to IBAT and FCC.

In some embodiments, FCC is related to load conditions, battery temperature (TBAT), and/or battery aging degree (AGS).

In some embodiments, the step of generating a SOC change based on the voltage difference and the gain (step 1006) includes: estimating a weight using a voltage weight model based on the battery voltage, wherein the voltage weight model defines a first preset relationship between the battery voltage and the weight, collected during the charging, discharging, and relaxing of the battery; estimating a fuzzy voltage difference using a voltage difference model based on the voltage difference, wherein the voltage difference model defines a second preset relationship between the voltage difference and the fuzzy voltage difference; and generating the present SOC change based on the weight, the fuzzy voltage difference, and the adjusted gain.

In some embodiments, the method 1000 of estimating the state of charge (SOC) of a battery further includes: collecting battery information under different charging/discharging currents before generating the next SOC (SOC_T+1).

In some embodiments, the method 1000 of estimating the SOC of a battery further includes: establishing the voltage weight model and the voltage difference model by estimating the SOC and the battery voltage under different charging/discharging currents.

In some embodiments, the method 1000 of estimating the SOC of a battery further includes: calculating the weight based on the difference in battery voltage between different charging/discharging currents to establish the voltage weight model.

In some embodiments, the method 1000 of estimating the SOC of a battery further includes: calculating the fuzzy voltage difference based on the charging/discharging current to establish the voltage difference model.

In some embodiments, the method 1000 of estimating the SOC of a battery further includes: generating the open-circuit voltage (OCV) by querying a preset relationship table between the SOC and the open-circuit voltage based on the SOC.

To establish the models used in the method of the present invention, the present invention adopts a standard charging and discharging process to collect battery information. For example, the invention observes the SOC and the battery voltage (VBAT) under different charging and discharging currents. Based on these observations, the present invention establishes two partner functions (or relationships): (1) a voltage difference between the battery voltage (VBAT) and the estimated open-circuit voltage (OCV) of the battery; and (2) an SOC change (ΔSOC) used to adjust the estimated SOC. Additionally, based on these observations, the present invention establishes another partner function (or relationship) between the SOC change (ΔSOC) and the battery voltage (VBAT). These two partner functions form a set of standard models, which can be optimized based on specific battery charging and discharging data. The specific battery data are derived from the most commonly used user experiences. Furthermore, by employing a minimized least square error algorithm, the optimal gain can be determined and the SOC change (ΔSOC) can be further refined by adaptively adjusting the gain based on the sensed battery current (IBAT). In addition, the gain control engine adaptively adjusts the gain based on the battery current (IBAT), so that even under conditions of dramatic changes in charging/discharging current, the present invention can still provide an accurate SOC. Moreover, the invention can provide a more accurate SOC under different battery loads, temperatures, capacities, and/or aging conditions.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A method of estimating a state of charge (SOC) of a battery, comprising:
(a) calculating a voltage difference (ΔV) using a voltaic gauge based on a battery voltage (VBAT) and an open-circuit voltage (OCV);
(b) adaptively adjusting a gain (K) using a gain control engine based on a battery current (IBAT) and a full charged capacity (FCC), wherein the gain (K) is adjusted to generate an adjusted gain (K′);
(c) generating a present SOC change (ΔSOC_T) using the voltaic gauge based on the voltage difference (ΔV) and the adjusted gain (K′); and
(d) generating a next SOC (SOC_T+1) using an accumulator based on a present SOC (SOC_T) and the present SOC change (ΔSOC_T).

2. The method of claim 1, wherein the step (b) further includes: adaptively adjusting the gain (K) using the gain control engine based on the gain (K) before adjustment and the voltage difference (ΔV) to generate the adjusted gain (K′).

3. The method of claim 1, wherein the steps (a), (b), (c), and (d) are executed sequentially, and after the step (d), the method repeats by using the next SOC (SOC_T+1) as the present SOC (SOC_T) in step (a).

4. The method of claim 3, wherein in the step (b), the gain control engine adjusts the gain by increasing or decreasing a fixed gain difference.

5. The method of claim 4, wherein in the step (b), the gain control engine further adjusts the gain based on a current difference between a previous battery current (IBAT_T−1) and the battery current (IBAT).

6. The method of claim 1, wherein in the step (b), when the voltage difference does not exceed a predetermined voltage difference or the battery current does not exceed a predetermined current, it is defined as a light-load condition, wherein the gain control engine adjusts and maintains the gain at a fixed light-load gain.

7. The method of claim 1, wherein the step (b) includes: the gain control engine compares a previous SOC change (ΔSOC_T−1) with a target change value (ΔSOCI) and adaptively adjusts the gain thereby, wherein the target change value (ΔSOCI) is related to the battery current and the full charged capacity (FCC).

8. The method of claim 1, wherein the full charged capacity (FCC) is related to a load condition, a battery temperature (TBAT), and/or a battery aging degree (AGS).

9. The method of claim 1, wherein the step (c) includes:
estimating a weight based on the battery voltage using a voltage weighting model, wherein the voltage weighting model is a first predetermined relationship between the battery voltage and the weight in battery information collected during charging, discharging, and relaxing;
estimating a fuzzy voltage difference based on the voltage difference using a voltage difference model, wherein the voltage difference model is a second predetermined relationship between the voltage difference and the fuzzy voltage difference; and
generating the present SOC change (ΔSOC_T) based on the weight, the fuzzy voltage difference, and the adjusted gain.

10. The method of claim 9, further comprising: before generating the next SOC (SOC_T+1), collecting battery information under different charging/discharging currents.

11. The method of claim 9, further comprising: establishing the voltage weighting model and the voltage difference model by estimating the SOC and the battery voltage under different charging/discharging currents.

12. The method of claim 11, further comprising: calculating the weight by a difference between battery voltages under the charging/discharging current and under a different charging/discharging current to establish the voltage weighting model.

13. The method of claim 1, further comprising: calculating the fuzzy voltage difference based on the charging/discharging current to establish the voltage difference model.

14. The method of claim 1, further comprising: generating the open-circuit voltage by querying a predetermined SOC and OCV relationship table based on the SOC.

15. A system of estimating an SOC of a battery, comprising:
a voltaic gauge, configured to calculate a voltage difference (ΔV) based on a battery voltage (VBAT) and an open-circuit voltage (OCV);
a gain control engine, configured to adaptively adjust a gain (K) based on a battery current (IBAT) and a full charged capacity (FCC), wherein the gain (K) is adjusted to generate an adjusted gain (K′); and
an accumulator, configured to generate a next SOC (SOC_T+1) based on a present SOC (SOC_T) and a present SOC change (ΔSOC_T);
wherein the voltaic gauge generates the present SOC change (ΔSOC_T) based on the voltage difference (ΔV) and the adjusted gain (K′).

16. The system of claim 15, wherein the gain control engine further adaptively adjusts the gain (K) based on the gain before adjustment (K) and the voltage difference (ΔV) to generate the adjusted gain (K′).

17. The system of claim 15, wherein the gain control engine adjusts the gain by iteratively increasing or decreasing a fixed gain difference.

18. The system of claim 17, wherein the gain control engine further adjusts the gain based on a current difference between a previous battery current (IBAT_T−1) and the battery current (IBAT).

19. The system of claim 15, wherein the gain control engine defines a light-load condition when the voltage difference does not exceed a predetermined voltage difference or the battery current does not exceed a predetermined current, and adjusts and maintains the gain at a fixed light-load gain.

20. The system of claim 15, wherein the gain control engine compares a previous SOC change (ΔSOC_T−1) with a target change value (ΔSOCI) and adaptively adjusts the gain thereby, wherein the target change value (ΔSOCI) is related to the battery current and the full charged capacity (FCC).

21. The system of claim 15, wherein the full charged capacity (FCC) is related to a load condition, a battery temperature (TBAT), and/or a battery aging degree (AGS).

22. The system of claim 15, wherein the voltaic gauge includes:
a weighted fuzzifier, configured to estimate a weight based on the battery voltage using a voltage weighting model, wherein the voltage weighting model is a first predetermined relationship between the battery voltage and the weight in a battery information collected during charging, discharging, and relaxing;
a voltage difference fuzzifier, configured to estimate a fuzzy voltage difference based on the voltage difference using a voltage difference model, wherein the voltage difference model is a second predetermined relationship between the voltage difference and the fuzzy voltage difference;
a multiplier, configured to perform multiplication on the weight and the fuzzy voltage difference to obtain their product; and
a compensator, configured to compensate or calibrate the product of the weight and the fuzzy voltage difference based on the adjusted gain to generate the present SOC change (ΔSOC_T).

23. The system of claim 22, wherein the weighted fuzzifier and the voltage difference fuzzifier establish the voltage weighting model and the voltage difference model under different charging/discharging currents based on corresponding different SOCs and different battery voltages.

24. The system of claim 23, wherein the weighted fuzzifier calculates the weight based on the difference between the battery voltages at different charging/discharging currents to establish the voltage weighting model.

25. The system of claim 23, wherein the voltage difference fuzzifier calculates the fuzzy voltage difference based on the difference between the voltage differences at different charging/discharging currents to establish the voltage difference model.

26. The system of claim 15, wherein the voltaic gauge further includes a lookup table, configured to generate the open-circuit voltage by querying a predetermined SOC and OCV relationship table based on the SOC.

27. The system of claim 15, wherein the accumulator accumulates at least one previous SOC change using an inverse Z-transformation method to generate the present SOC (SOC_T).
